(19) United States
(12) Patent Application Publication
(10) Pub. No.: US 2003/0000568 A1
(43) Pub. Date: Jan. 2, 2003

(54) Encapsulated photovoltaic modules and method of manufacturing same

(75) Inventor: Ronald C. Gonsiorawski, Danvers, MA (US)

Correspondence Address: Nicholas A. Pandiscio, Pandiscio & Pandiscio, P.C., 470 Totten Pond Road, Waltham, MA, 02451-1914, US

(73) Assignee: ASE Americas, Inc.

(21) Appl. No.: 10/035,107

(22) Filed: Dec. 27, 2001

Related U.S. Application Data
(63) Continuation-in-part of application No. 09/882,593, filed on Jun. 15, 2001, now abandoned.

(51) Int. Cl. H01L 25/00

(52) U.S. Cl. 136/251

(57) ABSTRACT

An improved laminated photovoltaic solar cell module and method of manufacture are provided which are characterized by use of a zinc-based ionomer encapsulant to avoid chemical reaction degradation by residues of acidic solder flux at soldered solar cell connections.

This application is a continuation-in-part of copending U.S. application Ser. No. 09/882,593, filed Jun. 15, 2001.

This invention was made under DOE Subcontract No. ZAX-8-17647-10.

### FIELD OF THE INVENTION

This invention relates to manufacture of photovoltaic solar cell modules and more particularly to an improved encapsulation material and method of manufacturing modules employing that material.

### BACKGROUND OF THE INVENTION

Most photovoltaic solar cells, e.g., silicon solar cells, are relatively small, e.g. 2-6 inches on a side in the case of cells made from rectangular silicon wafers cut from EFG-grown bodies, with the result that their power output is small. Accordingly conventional industry practice using wafer-type cells is to use soldered conductors in the form of flexible flat ribbons (tabbing) to serially connect a row of cells in a string and to electrically connect several strings together in a selected series and/or parallel arrangement so as to form a physically integrated module with a correspondingly greater power output. The electrically inter-connected strings are terminated by electrical conductors that extend outside of the module so as to permit connection to another module and/or an exterior circuit. Two or more modules may be connected together in a selected series and/or parallel arrangement to form a larger array with correspondingly greater power output, with the modules being mounted so as to form an integrated unit.

For various reasons, including the need to mechanically support the brittle silicon cells, and also to protect them against environmental degradation, it is common practice to form photovoltaic modules as laminated structures. The laminated modules comprise protective front and back panels or sheets, with the front panel being made of glass or a stiff plastic material that is transparent to solar radiation. Although the rear panel, typically called the “backskin”, may be made of the same material as the front panel, the preferred and common practice is to make it of a different material, e.g. a material such as Tedlar® (Tedlar is the trade name for a polyvinyl fluoride polymer made by E. I. DuPont de Nemeurs Co.). Disposed between the front and back sheets so as to form a sandwich arrangement are the interconnected solar cells and a selected polymer material that encapsulates the cells and is bonded to both the cells and the front and back sheets. A necessary requirement of the encapsulant (at least that portion thereof that extends between the front sides of the cells and the transparent front panel) is that it be transparent to solar radiation.

Heretofore a large number of materials have been used or considered for use as encapsulants for solar cells, as disclosed by U.S. Pat. Nos. 5,478,402, issued Dec. 26, 1995 to J. Hanoka and 5,476,553, issued Dec. 19, 1995 to J. Hanoka et al. Until at least about 1995, ethylene vinyl acetate copolymer (commonly known as “EVA”) was considered the best encapsulant. However, as noted by the Hanoka patents, supra, EVA is not satisfactory. Among its limitations are that it decomposes under sunlight, with the result that it discolors and get progressively darker. Its decomposition also releases acetic acid, which in turn promotes further degradation, particularly in the presence of oxygen and/or heat.

More recently, as disclosed in said U.S. Pat. No. 5,478,402, it was disclosed that the problems attendant to use of EVA could be reduced by using an ionomer as the cell encapsulant. The term “ionomer” and the type of resins identified thereby are well known in the art, as evidenced by Richard W. Rees, “Ionic Bonding In Thermoplastic Resins”, DuPont Innovation, 1971,2(2), pp. 1-4, and Richard W. Rees, “Physical Properties And Structural Features Of Surlyn Ionomer Resins”, Polyelectrolytes, 1976, C, 177-197. By way of example, ionomers may be formed by partial neutralization of ethylene-methacrylic acid copolymers or ethylene-acrylic acid copolymers with organic bases having cations of elements from Groups I, II, or III of the Periodic Table, notably, sodium, zinc, aluminum, lithium, magnesium and barium.

The laminated modules disclosed in the Hanoka '402 patent were constructed by assembling a sandwich comprising in order a top glass panel, at least one top sheet of ionomer encapsulant, an array of solar cells interconnected by electrical conductors, at least one back sheet of ionomer encapsulant, and a back panel, and then bonding those components together under heat and pressure. The Hanoka '402 patent teaches that a sodium-based ionomer is preferred as the first ionomer layer engaged with the top glass panel, and also suggests that use of a zinc-based ionomer should be limited to the back sheet since the light transmissibility of zinc-based ionomers is inferior to that of sodium-based ionomers. The Hanoka '402 patent discloses two sodium-based ionomers for use as encapsulant, namely, the SURLYN 1601 and SURLYN 1707 products produced by DuPont, with the former being described as having excellent optical properties and high hot tack strength and being preferred as yielding the best results. In U.S. Pat. No. 5,476,553 Hanoka et al. disclose incorporation of a UV absorber and a UV stabilizer in their sodium-based ionomer resin. Hanoka specifies that the lamination be conducted by heating the sandwich to a temperature of about 170 to 180° C. within about 10 to 15 minutes, and then holding the sandwich at that temperature for between about 10 to 20 minutes while simultaneously compressing together the several layers of the sandwich under a pressure in the range of about 14 to 14.6 psi (724 to 755 torr). The 170° C. temperature is required to cause the sodium ionomer to soften and flow into encapsulating relation with the cells and the interconnecting conductors. Thereafter, the heating is terminated and the pressure is relieved. The assembly is allowed to cool to the ambient temperature, causing the ionomer to solidify and bond to the cells, the interconnecting conductors, and the front and back panels.

However, modules made using sodium-based ionomers containing a UV absorber and stabilizer as taught by Hanoka et al have proven to be unsatisfactory for the reason that with time, often in a matter of months, portions of the transparent ionomer discolor. This discoloration, which occurs at multiple points along the length and breadth of the module, reduces the ionomer's light transmissibility, thereby lowering the module's energy conversion efficiency and power output, as well as rendering it less appealing from an aesthetic standpoint. It was determined also that if the UV absorber and stabilizer are omitted, discoloration of the sodium ionomer develops more slowly, with a gray cast developing within two to five years along with a broadband spectrum decrease in light transmission to cause a loss of photovoltaic performance. Another problem encountered in using a sodium ionomer encapsulant is that the relatively high temperatures (170 to 180°) and pressures (724 to 755 torr), and the dwell time at those conditions, are critical to achieving the desired bond strength and also costly to achieve. More importantly, because silicon solar cells are generally thin and brittle, the relatively high laminating pressures tend to cause an increase in the incidence of cell fracture during the lamination process.

Accordingly there has existed a need to overcome or substantially reduce the problems attendant to use of a sodium-based ionomer as an encapsulant for solar cells, particularly a sodium-based ionomer containing UV protection additives as disclosed by Hanoka et al.

### OBJECTS AND SUMMARY OF THE INVENTION

The present invention is based on the discovery that the observed deterioration of the sodium-based ionomer encapsulant at multiple points in a solar cell module is due to the fact that the soldered connections for the multiple conductors that interconnect the encapsulated cells often have flux residues that present an acidic environment. Sodium-based ionomers are reactive to acid, with the result that acid reaction discolorations tend to occur in those portions of the sodium ionomer that come in contact with the soldered connections.

Accordingly the primary object of the invention is to overcome the discoloration problem that characterizes photovoltaic modules which employ a sodium ionomer as the encapsulant, especially sodium ionomer containing UV protection additives as disclosed by Hanoka et al.

Another object is to provide an improved laminated photovoltaic solar cell module that is capable of an extended useful life without any substantial degradation of its encapsulant.

A further object is to provide an improved photovoltaic solar cell module having a long useful life without any substantial loss of power output.

Still another object is to provide an improved method of manufacturing laminated solar cell modules.

A more specific object is to use as the cell encapsulant a light-transmitting ionomer that is resistant to acid reaction and also is capable of strong adherence to other components of a solar cell module.

The present invention attains the foregoing objects by making photovoltaic cell modules in which the cell encapsulant is a zinc-based ionomer that combines resistance to acid-reaction degradation with excellent light transmissibility and high tack strength. Use of a zinc-based ionomer also permits the laminating process to be conducted under moderate level, and readily achieved and controlled, temperature and pressure conditions that assure complete encapsulation of the solar cells with a high tack strength adherence to the front and/or back panels and without any thermal degradation of the ionomer.

Other features and advantages of the invention are set forth in the following detailed specification which is to be considered together with the accompanying drawings.

### BRIEF DESCRIPTION OF THE DRAWINGS

FIGS. 1 and 2 are diagrams illustrating the radiation transmission characteristics of two test specimens embodying zinc ionomer resins;

FIG. 3 is a cross-sectional view of an assembly of components used to manufacture a preferred form of solar module embodying the present invention, with the components shown spaced apart for convenience of illustration and description;

FIG. 4, is a schematic partially exploded view, illustrating a second form of solar module embodying the invention; and

FIG. 5, is a schematic cross-sectional view illustrating a third form of solar module embodying the invention.

### DETAILED DESCRIPTION OF INVENTION

An important requirement in manufacturing solar modules that comprise silicon solar cells is that the conductors (tabbing) used to interconnect the photovoltaic cells be secured in place by a solder that is capable of resisting thermal degradation, as taught by U.S. Pat. No. 5,074,920, issued Dec. 24, 1991 to R. C. Gonsiorawski et al. For “Photovoltaic Cells With Improved Thermal Stability”, which is incorporated herein by reference. In this connection, it should be noted that the solder may be applied separately or the conductors may be pre-tinned, i.e., provided with a solder layer, to facilitate the soldering process. In both cases, the solder or soldering process includes a flux composition for removing oxide films and ensuring wetting of surfaces. A preferred and efficient practice is to use pre-tinned conductors which also have been coated with a suitable flux composition. The fluxes commonly comprise an inorganic or organic acid or acid salt, e.g., a carboxylate or a benzoate compound such as the one sold under the trade name “Pentoate”. Although the flux compositions are designed to be eliminated by vaporization directly or via decomposition during the soldering process, in practice some flux residue may continue to exist at the soldered connection points in contact with the surrounding ionomer encapsulant. Because the flux residue tends to be present in a small amount and scattered throughout the module, its deleterious affect on the encapsulant may not be immediate or immediately visible. However, over time, particularly under relatively high ambient temperatures, the flux-induced degradation of the sodium ionomer can progress sufficiently to adversely affect the power output and stability of the module.

The present invention overcomes the problem of flux-induced ionomer degradation by using a zinc-based ionomer as the encapsulant. It has been determined that zinc-based ionomers exist that are transparent, stable and capable of bonding adjacent components of a solar cell module. Such zinc-based ionomers are exemplified by two DuPont products identified as SURLYN 1705-1 and SURLYN 1706. These polymers have excellent optical properties and high hot tack strength. The exact chemical composition of these materials is not known, but they are believed to be produced by adding a salt containing zinc cations to a copolymer of ethylene-methacrylic acid, or to a copolymer of ethylene-acrylic acid, and subjecting that composition to acid neutralization, resulting in the formation of ion clusters within the resulting polymer matrix. The SURLYN 1705 composition is preferred since the SURLYN 1706 is more viscous and has a somewhat higher melting temperature. The properties of the SURLYN 1705 product as a resin and also in sheet form are set forth Tables I and II respectively:

TABLE I

| Resin Property | Typical Value | Test Method |
|---|---|---|
| Melt Flow Index | 5.5 | ASTM D1238 |
| dg/min. | | Cond. 190° C./2.16 kg |
| Melt Point, ° C. (° F.) | 95 (203) | ASTM D3418 |
| | | (DSC) |
| Freeze Point ° C. (° F.) | 61 (142) | ASTM D3418 |
| | | (DSC) |
| Vicat Softening Point | 65 (149) | ASTM D1525 |
| ° C. (° F.) | | |
| Ion Type | Zinc | |
| Density, g/cc | 0.95 | ASTM D792 |

TABLE II

| Film Property | | |
|---|---|---|
| (2 mil Blown, 3:1 BUR) | Typical Value | Test Method |
| Color | Clear and | |
| | Colorless | |
| Ultimate Tensile Strength | | |
| MD, psi (MPa) | 5300 (37) | |
| TD, psi (MPa) | 5100 (36) | ASTM D882 |
| Ultimate Elongation | | |
| MD/TD, % | 350/400 | ASTM D882 |
| Secant Modulus | | |
| MD, psi (MPa) | 35,000 (240) | |
| TD, psi (MPa) | 34,000 (230) | ASTM D882 |
| Gloss, 20° | 70 | ASTM D2457 |
| % Haze | 3.0 | ASTM D1003 |

In accordance with the preferred embodiment of the invention, additives for mitigating UV-induced photoxidation are incorporated in the zinc ionomer. Preferably the additives are added in amounts ranging from about 0.3 to about 1.0 wt. % and consist of a UV light absorber in the form of Tinuvin 328, a product manufactured by Geigy Chemical Corporation of Ardsley, N.Y., which is believed to be 2-(2H-benzotriazol-2-yl)-4,6-ditertpentylphenol, and a UV stabilizer in the form of Chimasorb 944, also a product manufactured by Geigy Chemical Corporation, which is identified by the manufacture as a sterically hindered amine light stabilizer (commonly identified as HALS).

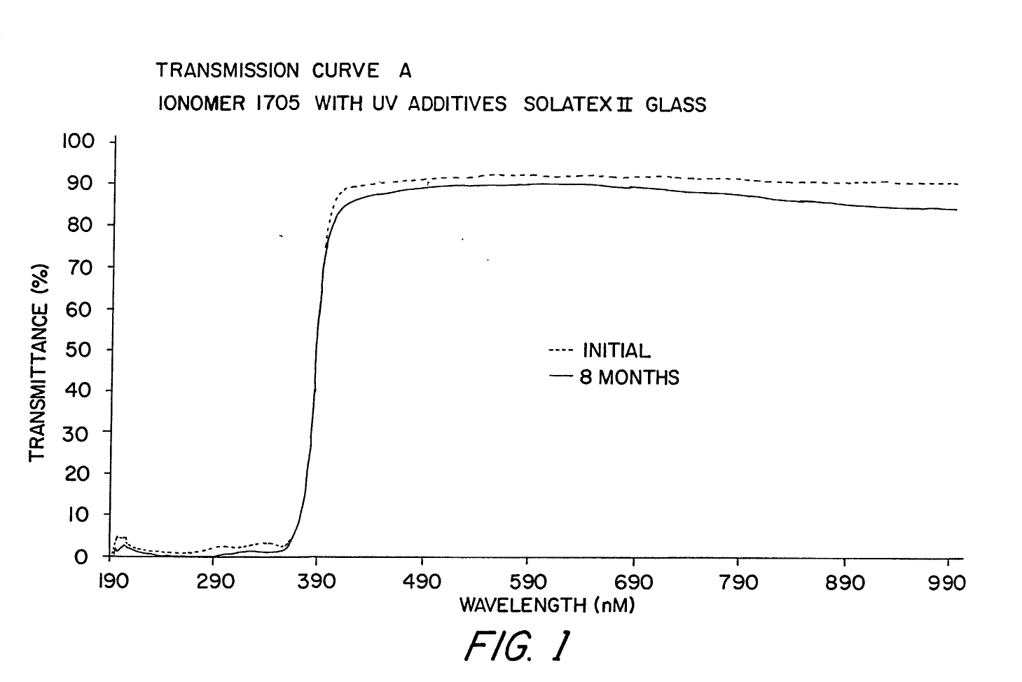

Test specimens, each comprising two 0.010 inch thick layers of Surlyn 1705, modified with 0.3 wt % Tinuvin and about 0.3 2 t. % Chimasorb 944, disposed between and bonded to two sheets of glass, showed improved radiation transmission in the 400 to 800 nM wavelength region and, more importantly, the specimens resisted photoxidation and maintained their high transmission properties in that wavelength region without discernible color alteration after prolonged and intense radiation stress exposure. More specifically, the test specimens were made using two different glasses. In one case, the front and back glass sheets were Solatex II glass (a tempered solar grade glass). In the other case, the two glass sheets were a borosilicate glass. FIGS. 1 and 2 illustrate the radiation transmission curves for test specimens made with Solatex II glass and borosilicate glass respectively. It is clear that in both cases, the transmission property for each specimen after 8 months exposure to the test condition is virtually the same as what it was immediately after fabrication and before testing.

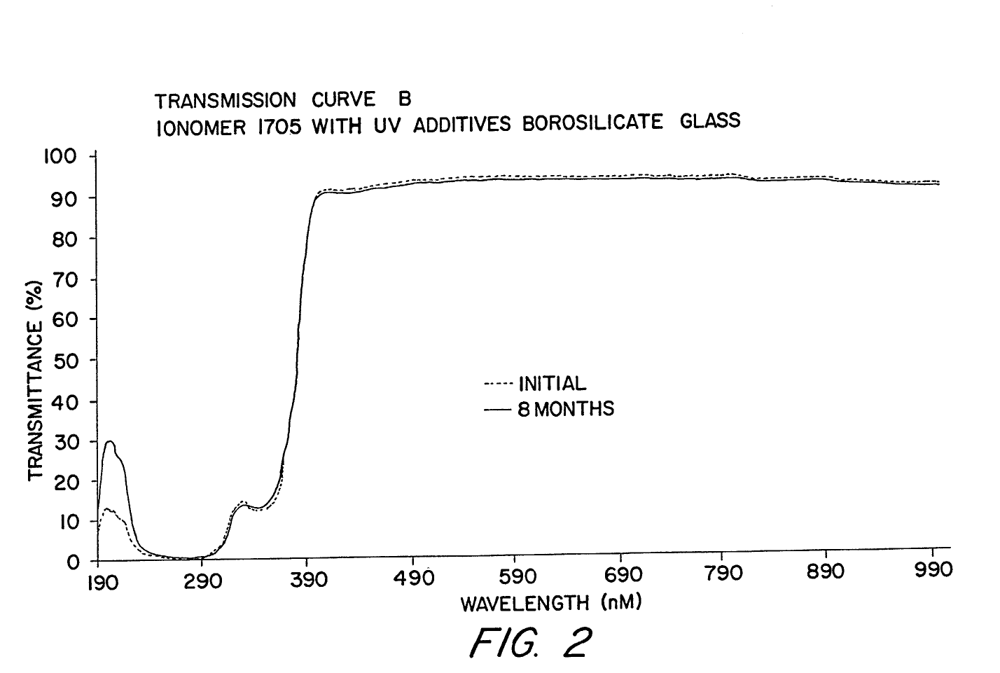

Referring now to FIG. 3 (wherein the thicknesses of the components are not intended to be to scale), manufacture of a solar module according to a preferred embodiment of this invention comprises assembling the following components in the order named, with the first named component on the bottom: a transparent front panel (“superstrate”) 2, a first layer 4 of a transparent zinc ionomer encapsulant, an array of wafer-type silicon solar cells 6 interconnected by conductors 8 (e.g., as illustrated in said Hanoka U.S. Pat. No. 5,478,402.), a porous scrim sheet 10, a second layer 12 of a transparent zinc ionomer encapsulant, and a protective back sheet or panel 14 in the form of Tedlar or some other suitable material. Each cell has a first electrode or contact on its front radiation-receiving surface and a second electrode or contact on its back surface, with the conductors 8 being soldered to those contacts to establish the desired electrical circuit configuration. Still referring to FIG. 3, each of the layers 4 and 12 may comprise one or more sheets of zinc ionomer, depending upon the thickness in which the ionomer is commercially available. Preferably but not necessarily one surface of each sheet of zinc ionomer has been subjected to a corona discharge treatment to enhance the bonding adherence of the ionomer to adjacent components. Although not shown, it is to be understood that the solar cells are oriented so that their front contacts face the glass panel 2, and also the cells are arranged in straight rows, i.e., strings, with the several strings are connected by other conductors similar to conductors 8 and with the whole array having terminal leads that extend out through a side of the assembly of components. Preferably the front panel is a tempered solar grade like Solatex II or a borosilicate glass, and the back panel is made of Tedlar. After the sandwich has been assembled, it is transferred to a laminating apparatus where its components are subjected to the laminating process. The laminating apparatus is essentially a vacuum press having electrical heating means and a flexible wall or bladder member that coacts with another rigid wall member or platen to compress the components together when the press is closed and evacuated. The assembly is positioned with the glass panel on the bottom in engagement with the rigid platen. Then the press is operated so as to heat the assembly in vacuum to a temperature in the range of about 115° C. to about 130° C., preferably about 125° C., with the pressure applied to the components increasing at a selected rate to a level in the range of about 390 to about 410 torr maximum. These temperature and pressure conditions are maintained for about 3 to 10 minutes, preferably between about 3 to 8 minutes, to assure that the ionomer has flowed so as to fully encapsulate the interconnected cells and contact the front and back panels, after which the pressure is maintained at or near the foregoing maximum level while the assembly is allowed to cool to about 80° C. or less. Thereafter the applied pressure is terminated to end the lamination process, and the laminated module product is removed for further processing. Preferably the press is operated so that the assembled components of the module are heated to the desired maximum temperature level within about 7 to about 10 minutes, are held at that temperature for about 9 to about 13 minutes, and then allowed to cool. The pressure exerted on the sandwich of module components reaches the maximum level of 390 to 410 torr only after the assembled components have reached the desired maximum temperature in order to allow the ionomer to flow as required and also to assure full removal of air and moisture. Preferably, but not necessarily, the pressure is maintained at that maximum level for at least about 4 minutes but not exceeding about 8 minutes.

Following is a specific example of the preferred mode of practicing the invention to manufacture modules employing silicon solar cells.

### EXAMPLE

A sheet of tempered solar grade CeO-free glass, having a thickness of 3/16 inch, is placed face down on a supporting surface. Two 0.010 inch thick corona-treated sheets of Surlyn 1705 zinc based ionomer, modified with 0.30% Chimasorb 944 and 0.30% Tinuvin 328, are placed over the top surface of the glass sheet. An array of inter-connected silicon solar cells made from rectangular polycrystalline EFG-grown wafers is placed on top of the two Surlyn sheets, with the front contacts of the cells facing the glass sheet. The conductors interconnecting the solar cells have been soldered to the front and back contacts of the cells using a tin/silver solder as prescribed by Gonsiorawski in U.S. Pat. No. 5,074,920, and an acidic carboxylate flux. The ionomer sheets are oriented so that the corona-treated surface of one sheet engages the glass sheet, and the corona-treated surface of the second sheet faces the array of solar cells. A scrim layer with a thickness of about 0.005 inch is placed over the array of solar cells in contact with the back contacts of the cells and the interconnecting conductors. Then another 0.010 inch thick sheet of the same modified Surlyn 1705 zinc ionomer is placed over the scrim with its corona-treated surface facing away from the scrim, and that ionomer sheet is covered by a back sheet of Tedlar. The Tedlar has a thickness of approximately 0.0015 inch. The resulting sandwich-like assembly is placed in a vacuum press and laminated.

The lamination is conducted by operating the press so that the following operating conditions are established: (1) the assembly is heated from the ambient temperature to a temperature of about 120° C. over a period of about 8 minutes and during that time evacuation of the press is initiated to evacuate air and moisture; (2) a pressure gradient is progressively applied across the sandwich so as to reach a maximum of about 400 torr after the components have been at the maximum temperature of about 120° C. for about 2-5 minutes, (3) the venting is stopped so as to maintain the 400 torr pressure, and heating continues so as to maintain the components at the 120° C. level for about an additional 3-8 minutes, after which heating is terminated so as to allow the assembly to cool; (4) the pressure gradient is maintained at or slightly below 400 torr until the assembly has cooled to about 80° C.; and (5) thereafter the pressure gradient is reduced to zero and the press is opened to remove the resulting laminated product. In the laminated product the several ionomer sheets have formed a strong bond with adjacent components and also been fused to one another in between the cells and also at the periphery of the module. This laminated module product may then be provided with a surrounding aluminum frame to form a discrete solar panel, in the manner well known to persons skilled in the art, e.g. as disclosed by U.S. Pat. No. 5,762,720, issued Jun. 9, 1998 to Jack L. Hanoka et al and said U.S. Pat. No. 5,478,402, both of which are incorporated herein by reference.

Panels incorporating silicon solar cell modules made according to the present invention, e.g., as set forth in the foregoing example, have passed stress tests of 1000 hours of 85% RH/85% ° C. damp heat as well as the humidity-freeze cycling (85/85 to 0/−40) for 20 cycles without decreased electrical photovoltaic performance while fully satisfying the safety criteria of the wet and dry high voltage withstand tests at 3600 volts as well as the insulation resistance criteria measured at 500 volts. This success using a Tedlar substrate is because the zinc ionomer encapsulant has a low water solubility which when coupled with the encapsulant's strong adherence capability avoids premature voltage breakdown and significant current conduction paths from cells to ground. By way of comparison, the zinc Surlyn 1705 material has a water absorption of 0.3 wt. % in comparison to the sodium Surlyn 1601 and EVA which have water absorption s of 3.0 wt. % and 0.7 wt. % respectively. Moreover, the condition of the physical structure of the solar modules is virtually unchanged from its pre-stress state and that includes the absence of (a) liquid water droplets that cause other encapsulant systems like EVA to become hazy and (b) the development of blisters beneath the Tedlar substrate resulting from hydrolytic attack at the underlying encapsulant interface.

To summarize, and in addition to what has been described above, silicon solar cell modules made according to this invention offer the following advantages: (1) high and stable adherence of the zinc ionomer to the glass front panel (superstrate), the cells, and the Tedlar backskin (substrate); (2) the zinc ionomer flows melts and flows freely and also readily solidifies as it undergoes the moderate temperature excursion involved in the lamination process; (3) the encapsulant has low water solubility in addition to being substantially inert to acid flux residues; (4) the zinc ionomer's inherent resistance to photo-oxidation eliminates the need to use a CeO doped glass (as is required with certain other encapsulant materials, notably EVA and—to a lesser extent—sodium ionomer, to reduce discoloration from 400 to 800 nM wavelength radiation); and (5) the low pressure gradient and moderate temperatures reduce the incidence of cell fracture.

Obviously it is possible to modify the components of the solar modules and the method of laminating the components without departing from the scope of the invention. Although modules made according to the invention using a non-CeO doped glass as the front panel show advantages over the prior art with respect to the ionomer encapsulant resisting photoxidation and maintaining solar radiation transmission in the 400 to 800 nM wavelength range and are preferred due to the reduced cost of such glass, the invention may be practiced using a CeO-doped solar glass front panel where cost is not a controlling factor. Also the glass front panel may be replaced by a sheet of a transparent plastic material, e.g., a polycarbonate or an acrylic polymer, while the backskin or rear panel may be made of glass or some other transparent, translucent or opaque material, e.g., a multi-composition laminate. It is also within the scope of the invention to vary one or more of the parameters of the laminating process, including but not limited to: (a) the rate at which the components are heated up to the desired maximum temperature, (b) the rate at which the compressive pressure exerted on the modules is increased to the desired maximum level, and (c) the length of time that the components are subjected to the maximum temperature and pressure conditions. The number and thickness of the zinc ionomer sheets used in making the module also may be varied. The Surlyn 1705 zinc ionomer may be replaced by the SURLYN 1706 zinc ionomer which also has a high radiant energy transmissibility. However, use of the SURLYN 1706 zinc ionomer is not preferred since it requires that the lamination proceed at a temperature in the range of about 160° C. to about 185° C. Other zinc ionomers resistant to acids and having a comparable low moisture absorption also may be used so long as they meet the following requirements: acceptable light transmission, adequate bonding adherence, high melt flow, and resistance to photoxidation. It is to be understood also that other UV absorbers and stabilizers may be found to be acceptable substitutes for the Tinuvin 3289 and Chimasorb 944.

Also the invention may be used in the manufacture of modules comprising different forms of solar cells known to persons skilled in the art. Silicon solar cells of the type contemplated herein and also in U.S. Pat. Nos. 5,478,402 and 5,476,553, supra, comprise silicon wafers with a p-n junction formed by doping, as disclosed, for example, in U.S. Pat. No. 4,751,191, issued Jun. 14, 1988 to R. C. Gonsiorawski et al, and U.S. Pat. No. 5,178,685, issued Jan. 12, 1993 to J. T. Borenstein et al. The invention may be used also in modules that comprise other cells formed independently of one another but interconnected by soldered conductors, notably cells comprising a semiconductor substrate such as germanium or gallium arsenide onto which one or more layers of another crystalline material are epitaxially grown to form one or more junctions, as disclosed, for example, in U.S. Pat. No. 5,944,913, issued Aug. 31, 1999 to H. Q. Hou et al. and U.S. Pat. No. 6,252,287, issued Jun. 26, 2001 to S. R. Kurtz et al. The invention also may be incorporated in modules that comprise so-called thin film solar cells. Typically such solar cell modules are produced by depositing several thin film layers on a substrate such as glass, with the layers being patterned so as to form a plurality of individual cells that are electrically interconnected to provide a suitable voltage output. Depending on the sequence in which the multi-layer deposition is carried out, the glass substrate may function as the back surface or as a front window for the module. By way of example, thin film solar cells are disclosed in U.S. Pat. Nos. 5,512,107, issued Apr. 30, 1996 to R. van der Berg; 5,948,176, issued 9/7199 to K. V. Ramanathan et al.; 5,994,163, issued Nov. 30, 1999 to M. Bodegard et al.; 6,040,521, issued Mar. 21, 2000 to K. Kushiya et al; 6,137,048, issued Oct. 24, 2000 to X. Wu; and 6,258,620, issued Jul. 10, 2001 to D. L. Morel et al.

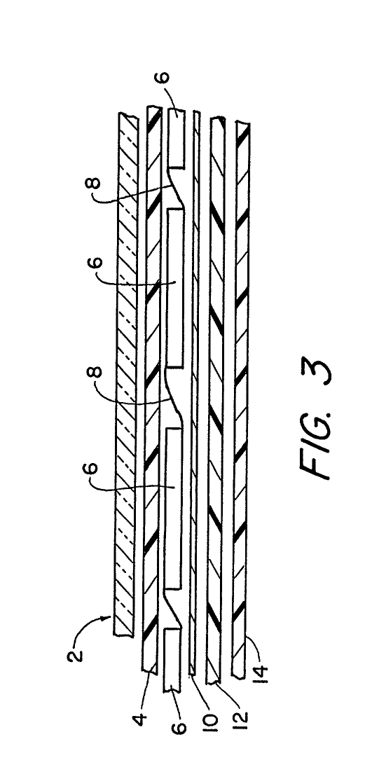

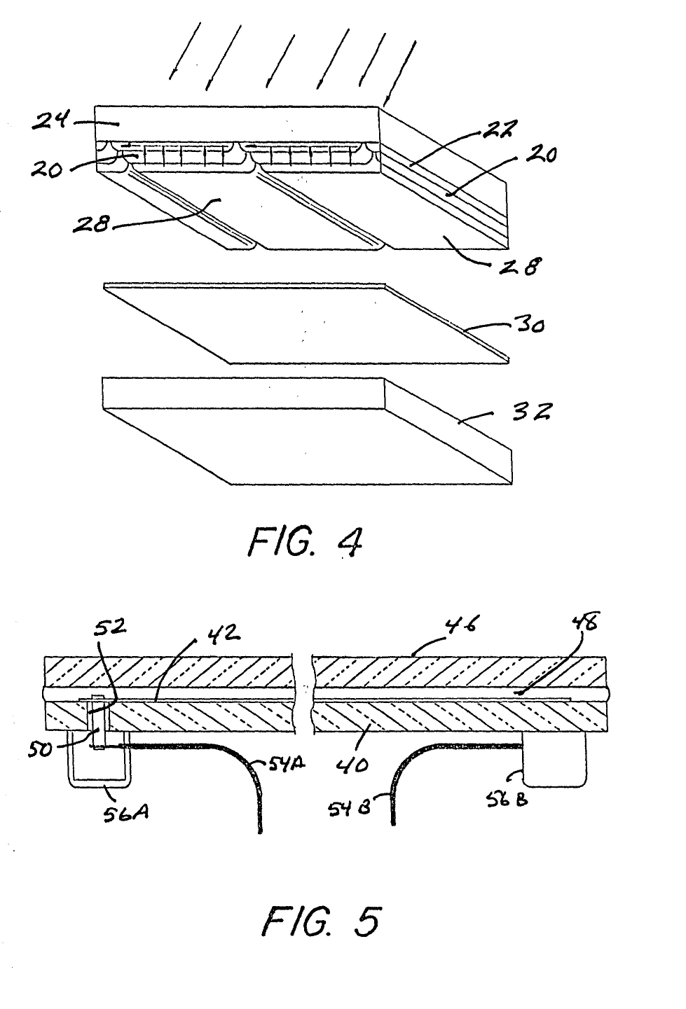

FIGS. 4 and 5 illustrate application of the invention to modules of thin film solar cells. In FIG. 4 the module comprises cadmium telluride thin film solar cells. In this embodiment of the invention, a plurality of cadmium telluride solar cells 20 are formed on a transparent conductive oxide film 22 which was deposited previously on a transparent glass superstrate 24. Thin film cadmium telluride solar cells are well known to persons skilled in the art. Each cell is provided with a back contact 28. The cells are coupled in series by monolithic connections (not shown). The module also includes at least one sheet 30 of the zinc ionomer, preferably the Surlyn 1705-1 product, and a rear glass plate 32. The ionomer sheet 30 and glass plate 32 are brought together with the other components, with the ionomer sheet covering the array of solar cells and covered by the rear glass plate 32. Although not shown, it is understood that the array of cells 20 (and preferably also the oxide film 22) do not extend to the perimeter of superstrate 24. The ionomer sheet is large large enough to extend beyond the perimeter of the array of cells, and preferably it extends to the edges of superstrate 24 and rear glass plate 32. Also, although omitted from FIG. 4 (and also from FIG. 5) for convenience of illustration, it is to be understood that wire leads are soldered to the opposite ends of the array of cells whereby the module may be electrically connected to another module or to an external circuit. The resulting assembly is placed in a vacuum press and subjected to heating under pressure, with the temperature and pressure being the same as described above in connection with the manufacture of silicon solar cell modules, with the result that the ionomer encapsulates and bonds to the cells and any exposed surfaces of the superstrate 24 surrounding the cells, and also bonds to the rear glass plate 32. The result is a sealed module which has a high resistance to delamination and provides excellent and durable protection of the cells and their terminal leads from the surrounding atmosphere. By way of example but not limitation, such modules may be made relatively large, e.g., rectangular modules measuring 600 mm×1000 mm.

Further by way of example, FIG. 5 illustrates application of the invention to a module comprising CIGS solar cells. The term “CIGS” identifies cells that comprise a thin film of Cu(InGa)(SeS)₂. Cell of this type are well known, as shown, for example, by U.S. Pat. No. 5,981,868, cited supra. In this case the module consists of a substrate 40 which may be made of glass or some other material, a plurality of series interconnected CIGS thin film solar cells represented generally at 42, a front glass plate 46, and an encapsulant layer 48 consisting of a zinc ionomer according to the present invention, preferably the Surlyn 1705-1 product. In this illustrated embodiment, the array of cells 42 does not extend to the perimeters of substrate 40 and glass plate 46, and the ionomer layer 48 extends beyond and overlaps the perimeter of the array of cells. The ionomer is bonded to the substrate 40 beyond the edges of the array, and also is bonded fully and directly to glass plate 46. A terminal tab 50 is connected to one end of the array of cells 42 and extends through a hole 52 in substrate 40, where it is soldered to an output cable 54A. A housing 56A attached to substrate 40 conceals and protects the soldered connection of tab 50 and cable 54A. A second output cable 54B is soldered to a terminal tab (not shown) attached to a cell (not shown) which forms the other end of the module, whereby cables 54A and 54B permit the module to be electrically coupled to another module or to an exterior circuit. A second housing 56B attached to substrate 40 conceals and protects the soldered connection of cable 54B to the module. The result is a sealed module with an improved resistance to discoloration and delamination and a long useful life. In this embodiment, as in that shown in FIG. 4, the zinc ionomer avoids chemical reaction degradation by residues of acidic solder flux at soldered solar cell connections. By way of example but not limitation, such modules may be made relatively large, e.g., rectangular modules measuring 600 mm×1000 mm.

Still other modifications and advantages of the invention will be obvious to persons skilled in the art from the foregoing specification and the following claims.

What is claimed is:

1. In a photovoltaic module of the type having an array of electrically interconnected photovoltaic cells encapsulated between a transparent front panel and a back sheet by a light-transmitting ionomer, the improvement wherein said light-transmitting ionomer is a zinc-based ionomer.

2. The combination according to claim 1 wherein said ionomer is an ethylene-methacrylic acid copolymer or an ethylene-acrylic acid copolymer.

3. The combination according to claim 1 wherein said front panel is made of glass and said rear sheet is made of Tedlar.

4 The combination according to claim 1 wherein each of said cells has front and back contacts and said cells are interconnected by conductors that have been soldered in place using an acidic flux.

5 The combination according to claim 1 wherein said ionomer is the product identified as Surlyn 1705-1.

6. The combination according to claim 6 wherein said ionomer has been modified by the addition of the UV absorber identified as Chimasorb 944 and the UV stabilizer identified as Tinuvin 328.

7. The combination according to claim 1 wherein said zinc ionomer is resistant to acid chemical attack.

8. The combination according to claim 7 wherein said zinc ionomer has low water solubility and melts at a temperature of about 95° C.

9. A photovoltaic module comprising a transparent front support sheet, a back sheet, an array of photovoltaic cells with front and back electrical contacts disposed between said front support sheet and said back sheet, a plurality of electrical conductors interconnecting said cells, said conductors being physically and electrically connected to said contacts by solder, and an ionomer encapsulant extending between and bonded to said front support sheet and said back and surrounding and bonded to said cells and said conductors, characterized in that an acidic flux residue is present at least some of the soldered connections of said conductors to said cells, and said ionomer is a zinc ionomer that is substantially inert with respect to reaction with said acid flux acid residue.

10. A photovoltaic module according to claim 9 wherein said zinc ionomer melts at a temperature of about 95° C.

11. A photovoltaic module according to claim 9 wherein said front support sheet is a CeO-free glass that is transparent to radiation with a wavelength in the range of about 400 to about 800 nM

12. A photovoltaic module according to claim 1 wherein said solar cells are thin film solar cells.

13. A photovoltaic module according to claim 12 wherein said solar cells are coupled to one another by monolithic connections.

14. A photovoltaic module according to claim 1 characterized by cadmium telluride solar cells.

15. A photovoltaic module according to claim 1 characterized by CIGS solar cells.

16. A method of manufacturing a photovoltaic module comprising the steps of:
(a) providing one or more strings of electrically interconnected photovoltaic cells, each cell having a front light-receiving surface and a rear surface with first and second contacts attached to said front and rear surfaces respectively, and said cells being interconnected by conductors that are soldered to said contacts;
(b) providing front and back support sheets with said front support sheet being stiff and transparent;
(c) placing a first zinc ionomer sheet in overlying relation with one surface of said front support sheet;
(d) placing said one or more strings of cells in overlying relation with at least one sheet of zinc ionomer;
(e) placing a sheet of scrim in overlying relation with said one or more strings of cells;
(f) covering said sheet of scrim with one or more additional sheets of zinc ionomer;
(g) placing said second support sheet in overlying relation with said one or more additional sheets of zinc ionomer; and
(h) heating the resulting assembly of said sheets and one or more strings of cells to a temperature in the range of about 120° C. to about 130° C. and compressing said components together under a pressure in the range of about 390 to about 400 torr, so as to cause said zinc ionomer sheets to soften enough to encapsulate said cells and conductors; and
(i) cooling said assembly so as to cause said ionomer to form a solid bond to said cells, conductors, scrim and front and rear support sheets, whereby to produce a laminated module.

17. A method according to claim 16 wherein step (h) is conducted with said assembly disposed in a vacuum laminating apparatus having a flexible wall, and the compression of the components of said assembly is accomplished by evacuating said apparatus, whereupon air is expelled from between said sheets and said flexible wall is drawn into tight compressing relation with said assembly.

18. A method according to claim 16 wherein the zinc ionomer in said module exhibits high radiation transmission in the 400 to 800 nM wavelength region.

19. A method according to claim 18 wherein said zinc ionomer is resistant to acid chemical attack.

20. A method according to claim 19 wherein said zinc ionomer has low water solubility and melts at a temperature of about 95° C.

21. A method according to claim 20 wherein said zinc ionomer resists photoxidation and maintains high radiation transmission in the wavelength range of 400 to 800 nM.

22. A method according to claim 16 wherein said front support sheet is a CeO-free glass that is transparent to radiation having a wave-length in the range of 400 to 800 nM.
